(19) United States
(12) Patent Application Publication
(10) Pub. No.: US 2024/0401226 A1
(43) Pub. Date: Dec. 5, 2024

(54) INGOT PULLER APPARATUS INCLUDING AUTOMATED FEED ASSEMBLY FOR CHARGING SEMICONDUCTOR MATERIAL

(71) Applicant: GlobalWafers Co., Ltd., Hsinchu (TW)

(72) Inventors: Yu-Chiao Wu, Frontenac, MO (US); Chun Leung Shiu, New Taipei City (TW); Ming-Hsien Lai, Hsinchu County (TW)

(21) Appl. No.: 18/326,343

(22) Filed: May 31, 2023

(51) Int. Cl. C30B 15/08; C30B 15/10; C30B 15/14

(52) U.S. Cl. CPC C30B 15/08; C30B 15/10; C30B 15/14

(57) ABSTRACT

An ingot puller for producing a single crystal semiconductor ingot includes a housing defining a growth chamber, a crucible positioned within the growth chamber, an ingot receiving vessel defining an ingot receiving chamber connected with the growth chamber, and a feed assembly for charging semiconductor material to the crucible. The feed assembly includes a dumper for containing the semiconductor material and moveable in the ingot receiving chamber between a raised position and a lowered position. The dumper includes a bottom and a sidewall releasable from the bottom to allow the semiconductor material to exit the dumper. The feed assembly also includes opening pins selectively extendable into and retractable from the ingot receiving chamber. The opening pins engage the dumper when extended into the ingot receiving chamber to release the dumper sidewall from the dumper bottom as the dumper is moved towards the lowered position.

### FIELD

The field of the disclosure relates to ingot puller apparatus used to produce single crystal semiconductor ingots, and more particularly to an automated feed assembly for charging semiconductor material into a crucible.

### BACKGROUND

Single crystal silicon, which is the starting material for most processes for the fabrication of many electronic components such as semiconductor devices and solar cells, is commonly prepared by batch Czochralski (CZ) or Continuous Czochralski (CCZ) methods. In these methods, a polycrystalline source material, such as polycrystalline silicon (“polysilicon”), in the form of solid feedstock material is charged to a quartz crucible and melted, a single seed crystal is brought into contact with the molten silicon or melt, and a single crystal silicon ingot is grown by slow extraction.

Conventional apparatus that facilitate growth of single crystal silicon ingots include a furnace tank or housing that defines a growth chamber in which the crucible is positioned, an isolation valve connected to an outlet of the growth chamber, and an ingot receiving vessel connected to the isolation valve. During an ingot growth process, the isolation valve is opened to provide communication between the growth chamber and an ingot receiving chamber defined by the ingot receiving vessel. An initial charge of polycrystalline silicon material is added to the crucible through the isolation valve and the outlet of the growth chamber and subsequently melted. The ingot is grown by the slow extraction in which the growing ingot is pulled out from the growth chamber, through the open isolation valve, and into the ingot receiving chamber. The fully grown ingot is accommodated within the ingot receiving chamber. After the growth process, the isolation valve is closed and the ingot receiving vessel is removed from the isolation valve. The fully grown ingot is then removed from the ingot receiving chamber.

The initial charge of the polycrystalline silicon material is typically added to the crucible using a dumper that is lowered in the ingot receiving chamber towards the outlet of the growth chamber. The dumper includes a bottom and a sidewall releasably seated on the bottom that, when released, “opens” the dumper and allows the polycrystalline silicon material to exit therefrom and flow into the crucible. In existing growth apparatus, the dumper may be opened using an opener flange that is temporarily seated between the ingot receiving vessel and the isolation valve. The opener flange includes projections that extend into the ingot receiving chamber and engage the dumper being lowered therein to release the sidewall and thereby open the dumper. To perform an initial charging operation, an operator is required to manually install the opener flange. The opener flange must then be removed after the charging operation as the projections may otherwise contact and damage the ingot being pulled through the ingot receiving chamber.

The use of the opener flange and the manual installation and removal that this component requires introduces operational inefficiencies in the ingot growth process and limits the ability to provide an automated growth process using the apparatus. The use of the opener flange also creates the opportunity for operator error. For example, the opener flange may not be properly installed resulting in a mischarge (e.g., an undercharge) of the polycrystalline silicon material into the crucible. A need exists for an improved feed assembly used with ingot growth apparatus to charge polycrystalline silicon material that addresses the above-described disadvantages.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. These statements are to be read in this light, and not as admissions of prior art.

### SUMMARY

One aspect is an ingot puller for producing a single crystal semiconductor ingot, the ingot puller including a housing defining a growth chamber, a crucible positioned within the growth chamber, an ingot receiving vessel defining an ingot receiving chamber connected with the growth chamber, and a feed assembly for charging semiconductor material to the crucible. The feed assembly includes a dumper for containing the semiconductor material and opening pins selectively extendable into the ingot receiving chamber and retractable from the ingot receiving chamber. The dumper is moveable in the ingot receiving chamber between a raised position and a lowered position. The dumper includes a dumper bottom and a dumper sidewall extending from the dumper bottom, the dumper sidewall being releasable from the dumper bottom to allow the semiconductor material to exit the dumper. The opening pins engage the dumper when extended into the ingot receiving chamber to release the dumper sidewall from the dumper bottom as the dumper is moved towards the lowered position.

Another aspect is an ingot puller for producing a single crystal semiconductor ingot, the ingot puller including a housing defining a growth chamber and a growth chamber outlet, a crucible positioned within the growth chamber, a feed assembly for charging semiconductor material to the crucible, and a controller. The feed assembly includes a dumper for containing semiconductor material and opening pin assemblies. The dumper includes a dumper bottom and a dumper sidewall releasable from the dumper bottom to define a charge chute for the semiconductor material to exit the dumper, and the dumper is moveable between a raised position and a lowered position. The opening pin assemblies each include an opening pin selectively extendable into engagement with the dumper to release the dumper sidewall from the dumper bottom as the dumper is moved towards the lowered position. The charge chute is defined and located adjacent to the growth chamber outlet or within the growth chamber when the dumper is in the lowered position. Each opening pin assembly also includes an actuator that causes the opening pin to extend into engagement with the dumper. The controller controls each actuator to cause the respective opening pin to extend into engagement with the dumper.

Another aspect is a method of producing a single crystal semiconductor ingot from a semiconductor melt using an ingot puller. The method includes positioning a crucible within a growth chamber defined by a housing of the ingot puller; connecting an ingot receiving vessel defining an ingot receiving chamber to the housing; lowering a dumper in the ingot receiving chamber, the dumper containing semiconductor material; controlling, using a controller, opening pins to extend into the ingot receiving chamber to cause the dumper to open and allow the semiconductor material to exit the dumper and flow into the crucible; heating the semiconductor material to cause a semiconductor melt to form in the crucible; and pulling a single crystal semiconductor ingot from the semiconductor melt.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a schematic cross section of an ingot pulling apparatus for forming a single crystal silicon ingot;

FIG. 2 is a schematic cross section of the ingot pulling apparatus of FIG. 1, shown with an automated feed assembly;

FIG. 3 is a partial cross section of the ingot puller apparatus of FIGS. 1 and 2, showing a dumper of the feed assembly in a lowered and open position;

FIG. 4 is an isolated bottom section of an ingot receiving vessel of the ingot puller apparatus of FIG. 3 with the dumper positioned therein, taken along a line extending through opening pin assemblies perpendicular to a longitudinal axis of the ingot puller apparatus;

FIG. 5 is an enlarged perspective of one of the opening pin assemblies;

FIG. 6 is a cross section of the opening pin assembly of FIG. 5; and

FIGS. 7-9 are partial cross sections of the ingot puller apparatus of FIG. 3 and illustrate steps in a sequence of moving the dumper of the feed assembly from a raised position (FIG. 7) to a lowered position (FIGS. 8 and 9).

Corresponding reference characters indicate corresponding parts throughout the drawings.

### DETAILED DESCRIPTION

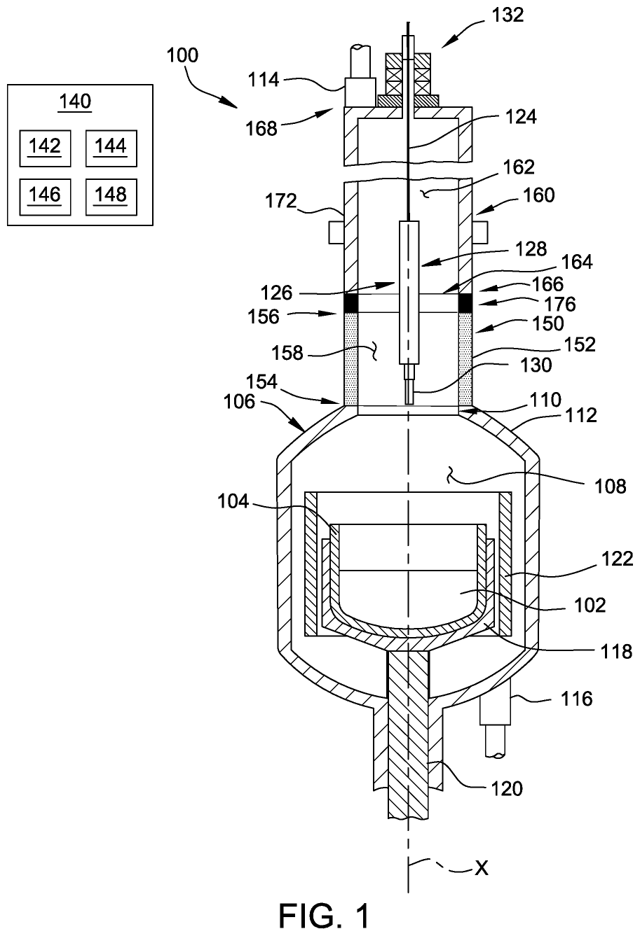

Referring to FIG. 1, a cross section of an example ingot puller apparatus or ingot puller is shown schematically and is indicated generally at 100. The ingot puller 100 is used to produce single crystal (i.e., monocrystalline) ingots of semiconductor material such as, for example, single crystal silicon ingots. In some embodiments, the ingot is grown by the so-called Czochralski (CZ) process in which the ingot is withdrawn from a semiconductor melt 102 (e.g., a silicon melt 102) held within a crucible 104 of crystal puller 100. In some embodiments, the ingot is grown by a batch CZ process in which polycrystalline semiconductor material (e.g., polycrystalline silicon) is charged to the crucible 104 in a suitable amount to grow one ingot, such that the crucible 104 is essentially depleted of the melt 102 after the growth of the one ingot. In other embodiments, the ingot is grown by a continuous CZ (CCZ) process in which polycrystalline semiconductor material (e.g., polycrystalline silicon) is continually or periodically added to crucible 104 to replenish the melt 102 during the growth process. The CCZ process facilitates growth of multiple ingots pulled from a single melt 102. Embodiments of the subject matter described are not limited to a particular crystal growth process, and may be used to grow ingots formed from a monocrystalline semiconductor material other than silicon.

The ingot puller 100 includes a housing 106 that defines a crystal growth chamber 108 and a growth chamber outlet 110 that has a smaller transverse dimension than the growth chamber 108. The housing 106 has a generally dome shaped upper wall 112 transitioning from the growth chamber 108 to the growth chamber outlet 110. The ingot puller 100 includes an inlet port 114 and an outlet port 116 which may be used to introduce and remove a process gas to and from the growth chamber 108 during crystal growth.

The crucible 104 within the ingot puller 100 contains the silicon melt 102 from which a silicon ingot is drawn. The crucible 104 may be made of quartz or fused silica, which has a high melting point and thermal stability and is generally non-reactive with molten silicon in melt 102. The crucible 104 may be made from other materials in addition to quartz without departing from the scope of the present disclosure. For example, the quartz crucible 104 may be made from a composite material that includes silica and an additional material, for example, silicon nitride or silicon carbide.

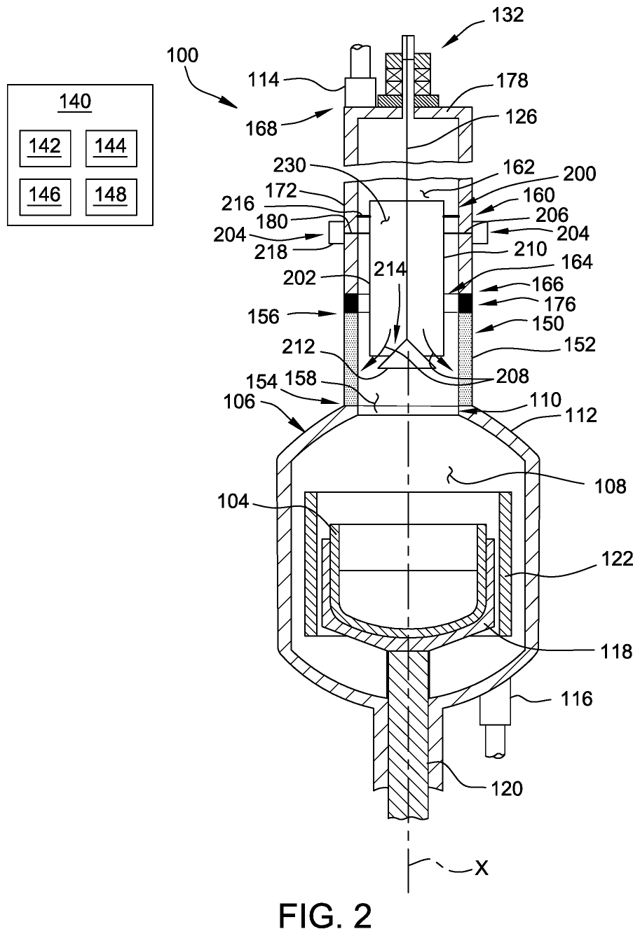

The silicon melt 102 is obtained by melting polycrystalline silicon charged to the crucible 104. The ingot puller 100 includes a feed assembly 200 (shown in FIG. 2) that facilitates charging the polycrystalline silicon material to the crucible 104. The feed assembly 200 is used for an initial charge of the polycrystalline silicon material to the crucible 104. The polycrystalline silicon material may be solid polycrystalline silicon. In some embodiments, the initial charge of the polycrystalline silicon material added using the feed assembly 200 may be continuously replenished to the crucible 104 using an auxiliary feed system (not shown). For example, the ingot puller 100 may be configured for producing ingots by a continuous CZ growth process, and may include a feed tube assembly (not shown) that extends through the housing 106 into the growth chamber 108 (not shown) for continuously feeding polycrystalline silicon material into the crucible 104 and/or the melt 102 during an ingot growth process.

The crucible 104 is positioned within and supported by a susceptor 118 that is in turn supported by a rotatable shaft 120. Susceptor 118 and rotatable shaft 120 facilitate rotation of the crucible 104 about a central longitudinal axis X of the ingot puller 100.

A heating system 122 (e.g., one or more electrical resistance heaters) surrounds the susceptor 118 and crucible 104 and supplies heat by conduction through the susceptor 118 and crucible 104 for melting the silicon charge to produce the melt 102 and/or maintaining the melt 102 in a molten state. The heater 122 may also extend below the susceptor 118 and crucible 104. The heating system 122 is controlled by a controller 140 so that the temperature of the melt 102 is precisely controlled throughout the pulling process. For example, the controller may control electric current provided to the heating system 122 to control the amount of thermal energy supplied by the heating system 122. The controller may control the heating system 122 so that the temperature of the melt 102 is maintained above about the melting temperature of silicon (e.g., about 1412° C.). For example, the melt 102 may be heated to a temperature of at least about 1425° C., at least about 1450° C. or even at least about 1500° C. Insulation (not shown) surrounding the heating system 122 may reduce the amount of heat lost through the housing 106. The ingot puller 100 may also include a heat shield assembly (not shown) above the surface of melt 102 for shielding the ingot from the heat of the crucible 104 to increase the axial temperature gradient at the solid-melt interface.

A pulling winch 132 is attached to a pull wire 124 that extends down from the winch. The winch 132 is capable of raising and lowering the pull wire 124 and rotating the pull wire 124. The ingot puller 100 may have a pull shaft rather than a wire, depending upon the type of puller. The pull wire 124 terminates in a pulling assembly 126 that includes a seed crystal chuck 128 which holds a seed crystal 130 used to grow the silicon ingot.

The ingot puller 100 also includes an isolation valve 150 connected to the housing 106 and, more specifically, to the upper wall 112 at the growth chamber outlet 110. The isolation valve 150 includes a valve body 152 that extends between a first valve end 154 connected to the housing 106 and a second valve end 156. A valve passageway 158 extends through the valve body 152 between the first and second valve ends 154 and 156. The valve body 152 is open at both valve ends 154, 156 such that the valve passageway 158 connects the growth chamber 108 and an ingot receiving chamber 162 defined by an ingot receiving vessel 160. The isolation valve 150 may be opened and closed to selectively provide communication between the growth chamber 108 and the ingot receiving chamber 162. The isolation valve 150 includes a valve element (not shown) positioned in the valve passageway 158 that may be selectively actuated, either automatically (e.g., by an actuating arm controllable by the controller 140) or manually by an operator using a valve handle (not shown) connected with the valve element, to close or open the valve passageway 158. The valve element may be a moveable disk that is actuated to selectively seal the second valve end 156, thereby closing the valve passageway 158. In other examples, the isolation valve 150 may include any suitable valve configuration and valve element(s) to enable the isolation valve 150 to function as described. For example, the isolation valve 150 may include a ball valve, a butterfly valve, a diaphragm valve, or any other suitable type of valve. When closed, the isolation valve 150 may suitably isolate the growth chamber 108 from the ingot receiving chamber 162 and/or the ambient environment.

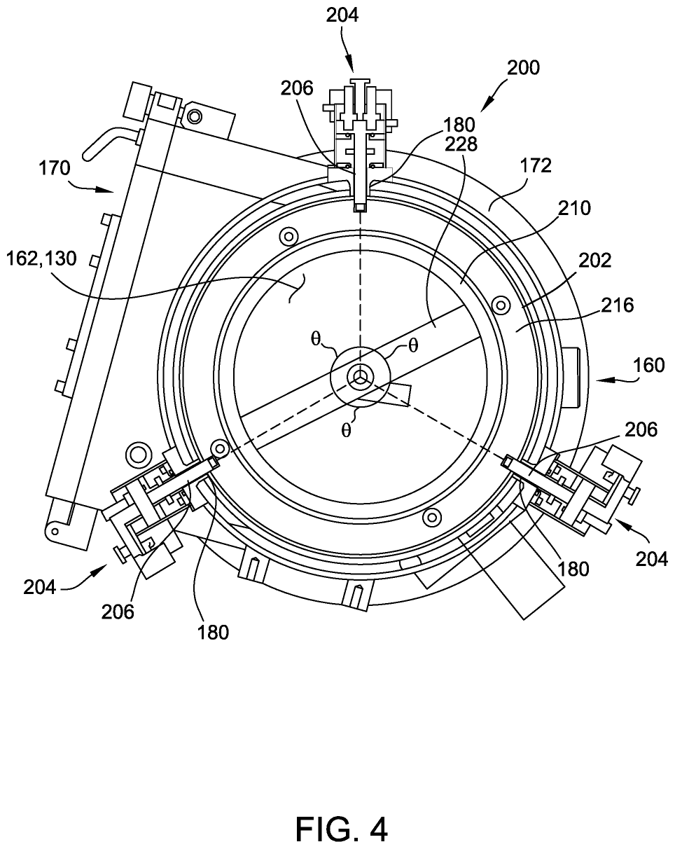

The ingot receiving vessel 160 includes a hollow cylinder that defines the ingot receiving chamber 162. The ingot receiving vessel 160 is open at a first vessel end 166 to define a receiving chamber inlet 164. The ingot receiving vessel 160 extends from the first vessel end 166 to a second vessel end 168. The ingot receiving vessel 160 includes a door 170 (shown in FIG. 4) located on a sidewall 172 of the receiving vessel 160. The sidewall 172 extends between the first and second vessel ends 166 and 168. When the ingot puller 100 is assembled during a growth process, the first vessel end 166 is connected to the second valve end 156 and secured thereto using a clamp 176. The receiving vessel 160 extends vertically above the isolation valve 150 and the housing 106 in coaxial alignment with the valve passageway 158 and the growth chamber outlet 110. More specifically, the receiving vessel 160, the isolation valve 150, and the growth chamber outlet 110 are axially aligned along the longitudinal axis X of the ingot puller 100 to enable the growing ingot to be pulled out of growth chamber 108 through the growth chamber outlet 110, through the valve passageway 158, and into the ingot receiving chamber 162. The receiving vessel 160 extends a suitable height between the first and second vessel ends 166 and 168 to accommodate the entire length of the fully grown ingot and the pulling assembly 126. The door 170 located on the sidewall 172 of the ingot receiving vessel 160 is sized and shaped to provide a lateral exit for the fully grown ingot from the receiving chamber 162.

A process gas (e.g., argon) is introduced through the inlet port 114 into the growth chamber 108 and is withdrawn through the outlet port 116. The inlet port 114 is shown positioned at the second vessel end 168 to introduce process gas through the ingot receiving chamber 162 and the open valve passageway 158 towards the growth chamber 108. In other examples, the inlet port 114 may be located at an additional or alternative suitable position in the ingot puller 100 (e.g., on the upper wall 112 of the housing 106). The process gas creates an atmosphere within the housing and the melt and atmosphere form a melt-gas interface. The outlet port 116 is in fluid communication with an exhaust system (not shown) of the ingot puller.

The controller 140 may be any known computing device or computer system and includes one or more processors 142 and a memory area 144. The processor 142 executes instructions stored in the memory area 144. The term “processor” refers to central processing units, microprocessors, microcontrollers, reduced instruction set circuits (RISC), application specific integrated circuits (ASIC), logic circuits, and any other circuit or processor capable of executing the functions described. The above are examples, and are thus not intended to limit in any way the definition and/or meaning of the term “processor.” In addition, one or more processors 142 may be in one computing device or a plurality of computing devices acting in parallel.

Stored in the memory area 144 are, for example, processor-executable instructions for receiving and processing input received from an operator (e.g., via a user interface 146) and controlling process parameters of the ingot puller 100 based on the processed input received from the operator. The memory area 144 may include, but is not limited to, any computer-operated hardware suitable for storing and/or retrieving processor-executable instructions and/or data. The memory area 144 may include random access memory (RAM) such as dynamic RAM (DRAM) or static RAM (SRAM), read-only memory (ROM), erasable programmable read-only memory (EPROM), electrically erasable programmable read-only memory (EEPROM), and nonvolatile RAM (NVRAM). Further, the memory area 144 may include multiple storage units such as hard disks or solid state disks in a redundant array of inexpensive disks (RAID) configuration. The memory area 144 may include a storage area network (SAN) and/or a network attached storage (NAS) system. In some embodiments, the memory area 144 includes memory that is integrated in controller 140. For example, the controller 140 may include one or more hard disk drives as the memory area 144. The memory area 144 may also include memory that is external to the controller 140 and may be accessed by a plurality of computing devices. The above memory types are for example, and are thus not limiting as to the types of memory usable for storage of processor-executable instructions and/or data.

The controller 140 also includes a user input device or user interface 146 for receiving input from an operator. The information may be one or more selected process parameters or control actions for an ingot growth process. The input device 146 may include, for example, a keyboard, a pointing device, a mouse, a stylus, a touch sensitive panel (e.g., a touch pad or a touch screen), an audio input device, and the like. A single component such as a touch screen may function as both an output device of the controller 140 (e.g., a media output component) and the input device 146. For example, the memory area 144 may store computer-readable instructions for providing the user interface 146 to a user via media output component and for receiving and processing input from the user interface 146. The user interface 146 may include, among other possibilities, a web browser and an application. Web browsers enable users to display and interact with media and other information typically embedded on a web page or a website from a web server. An application allows users to interact with a server application. The user interface, via one or both of a web browser and an application, facilitates display of information related to the ingot puller 100 and the ingot growth process.

The controller 140 may also include a communication interface 148, which may be communicatively connected to one or more remote devices. The communication interface 148 may include, for example, a wired or wireless network adapter or a wireless data transceiver for use with a mobile phone network (e.g., Global System for Mobile communications (GSM), 3G, 4G or Bluetooth) or other mobile data network (e.g., Worldwide Interoperability for Microwave Access (WIMAX)).

During operation of the ingot puller 100 to grow an ingot, the first vessel end 166 of the ingot receiving vessel 160 is connected to the second valve end 156 of the isolation valve 150 and secured thereto using the clamp 176. The isolation valve 150 is opened at this stage to provide communication between the growth chamber 108, the valve passageway 158, and the ingot receiving chamber 162. Polycrystalline silicon material is charged to the crucible 104 using the feed assembly 200, described in further detail below. The charge of polycrystalline silicon material in the crucible 104 is heated by the heating system 122 to produce the silicon melt 102. Process gas is introduced into the growth chamber 108 through the inlet port 114, the ingot receiving chamber 162, and the valve passageway 158. The winch 132 lowers the seed crystal 130 through the ingot receiving chamber 162 and the valve passageway 158 and into the growth chamber 108 until the seed crystal 130 contacts the surface of the silicon melt 102.

Once the seed crystal 130 begins to melt, the winch 132 slowly raises the seed crystal 130 up, in a direction of longitudinal axis X, through the growth chamber 108 to grow the single crystal ingot. The speed at which the winch 132 rotates the seed crystal 130 and the speed at which the winch 132 raises the seed crystal (i.e., the pull rate v) are controlled by the controller 140. As the seed crystal 130 is slowly raised from the melt 102, silicon atoms from the melt 102 align themselves with and attach to the seed crystal 130 to form an ingot. The winch 132 continues to raise the seed crystal 130 and the growing ingot in the direction of the longitudinal axis X, out of the growth chamber 108 through the growth chamber outlet 110 and into the ingot receiving chamber 162 through the valve passageway 158. After the ingot is grown a suitable length, the growth process terminates and the fully grown ingot is positioned within the receiving chamber 162. The isolation valve 150 is subsequently closed (either manually or via the controller 140) and the clamp 176 is opened to release the ingot receiving vessel 160 from the isolation valve 150. The ingot receiving vessel 160 is removed from the isolation valve 150 and the ingot is subsequently removed from the receiving chamber 162 via the door 170.

FIG. 2 is a schematic cross section of the ingot puller 100 with the feed assembly 200 installed for charging the polycrystalline silicon material into the crucible 104. The feed assembly 200 includes a dumper 202 and opening pin assemblies 204. Each of the opening pin assemblies 204 is connected to the sidewall 172 of the ingot receiving vessel 160 and includes an opening pin 206 that is selectively extendable into and retractable from the ingot receiving chamber 162 through a corresponding opening 180 in the sidewall. The dumper 202 is positioned in the ingot receiving chamber 162 and is lowered and raised along the longitudinal axis X, towards and away from the valve passageway 158 and the growth chamber outlet 110. The dumper 202 is axially aligned with the ingot receiving chamber 162, the valve passageway 158, and the growth chamber outlet 110 along the axis X.

The opening pins 206 selectively extend into the ingot receiving chamber 162, in a direction perpendicular to the axis X, as the dumper 202 is being lowered and engage the dumper 202 to cause the dumper 202 to open. The dumper 202 contains polycrystalline semiconductor material (e.g., solid polycrystalline silicon) that exits the dumper 202 when opened and flows through the growth chamber outlet 110 and into the crucible 104. The polycrystalline semiconductor material exiting the dumper 202 is indicated by the arrows 208 in FIG. 2.

In the example ingot puller 100, the dumper 202 is connectable with the pull wire 124 (e.g., via the pulling assembly 126) and the winch 132 is operable to raise and lower the dumper 202 in the ingot receiving chamber 162. The ingot receiving vessel 160 includes an end cap 178 that is integral with or connected to the sidewall 172 at the first end 168 (e.g., using fasteners). The winch 132 is seated on the end cap 178 and the pull wire 124 extends through the end cap 178. The winch 132 is used to lower and raise the dumper 202 during a charging operation and to lower the seed crystal 130 and raise the seed crystal 130 and growing ingot during an ingot growth process. In other examples, a different pulling mechanism (e.g., a different pulling winch) may be used between the charging operation and the ingot growth process.

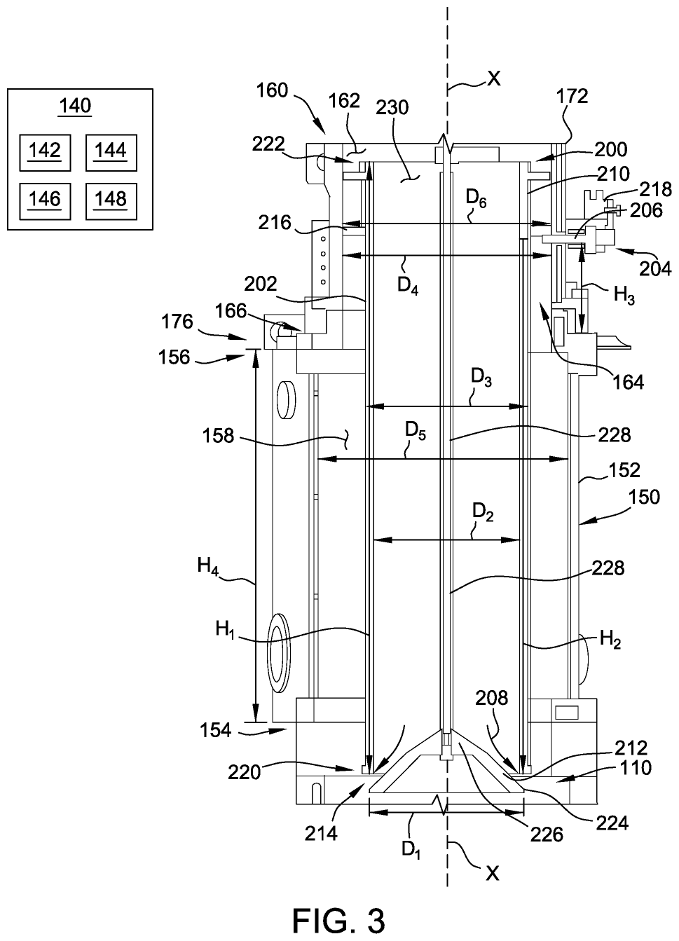

The dumper 202 includes a sidewall 210 (also referred to as a dumper sidewall 210) and a bottom 212 (also referred to as a dumper bottom 212). The sidewall 210 and the bottom 212 define an interior volume 230 of the dumper 202 that is sized to contain a suitable amount of polycrystalline semiconductor material for charging into the crucible 104 and subsequently forming the melt 102. The sidewall 210 defines a circumferential and longitudinal size and cross-sectional shape of the dumper 202. The sidewall 210 has any suitable cross-sectional shape, for example, the sidewall 210 may be cylindrical, prismatic, frusto-conical, or may have any other suitable shape. In the example dumper 202, the sidewall 210 is cylindrical. The cross-sectional size (e.g., an outer diameter D₃, shown in FIG. 3) of the sidewall 210 is suitably smaller than a cross-sectional size (e.g., an inner diameter D₄, shown in FIG. 3) of the ingot receiving vessel 160 to enable the dumper 202 to be lowered and raised within the ingot receiving chamber 162 without contacting the sidewall 172 of the ingot receiving vessel 160.

The dumper sidewall 210 is releasable from the bottom 212 to define a charge chute 214 therebetween through which the polycrystalline semiconductor material 208 exits the dumper 202. The bottom 212 is attached to the pull wire 124 (e.g., via the pulling assembly 126) and the sidewall 210 is seated on the bottom 212 as the dumper 202 is raised and lowered in the ingot receiving chamber 162. The dumper sidewall 210 includes an annular stop 216 extending outward therefrom. The annular stop 216 engages the opening pins 206 that extend into the ingot receiving chamber 162. When the dumper 202 is lowered and the opening pins 206 extend into the ingot receiving chamber 162, the annular stop 216 engages the opening pins 206, causing the sidewall 210 to release from the bottom 212. The bottom 212 continues to be lowered below the sidewall 210 along the axis X after the sidewall 210 is released therefrom, thereby opening the charge chute 214 for the polycrystalline semiconductor material 208 to exit therethrough.

Each opening pin assembly 204 includes the opening pin 206 and an actuator 218 that is operably connected to the opening pin 206. The actuator 218 is controllable to cause the opening pin 206 to extend into and retract from the ingot receiving chamber 162. In the example ingot puller 100, the actuator 218 is connected to the controller 140 that controls each actuator 218 to cause the respective opening pin 206 to extend into and retract from the ingot receiving chamber 162. In other examples, a separate controller may be included for controlling each opening pin assembly 204. The opening pin assembly 204 may additionally and/or alternatively be manually operable for causing the opening pin 206 to extend into and retract from the ingot receiving chamber 162. Any suitable number of opening pin assemblies 204 and/or opening pins 206 may be included to enable the feed assembly 200 to function as described herein. In the example feed assembly 200, three opening pin assemblies 204 are included. In some examples, more or fewer opening pin assemblies 204 may be included in the example feed assembly 200, such as one, two, four, five, six, seven, eight, or more than eight opening pin assemblies 204. Suitably, the opening pins 206 simultaneously engage the annular stop 216 along a common plane, perpendicular to the longitudinal axis X, to maintain axial alignment of the dumper 202 with the axis X when the dumper 202 is opened.

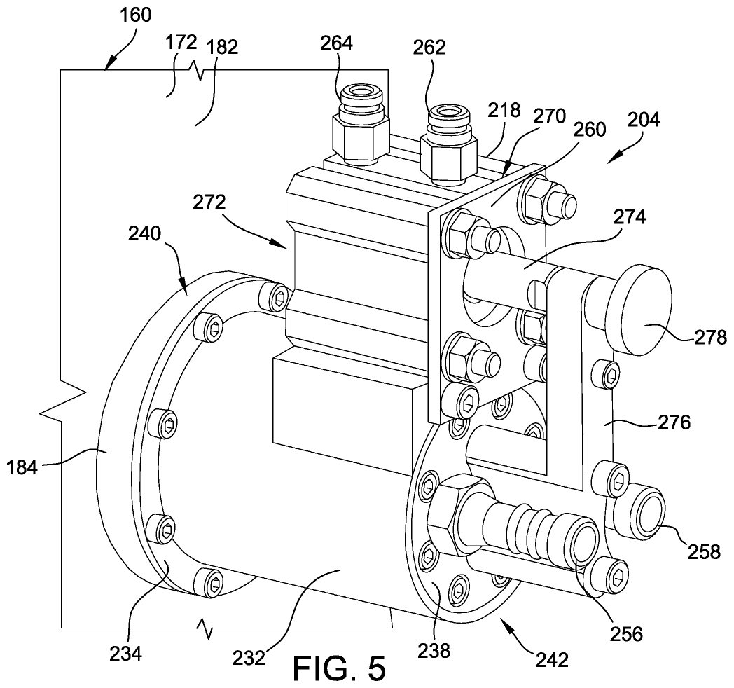

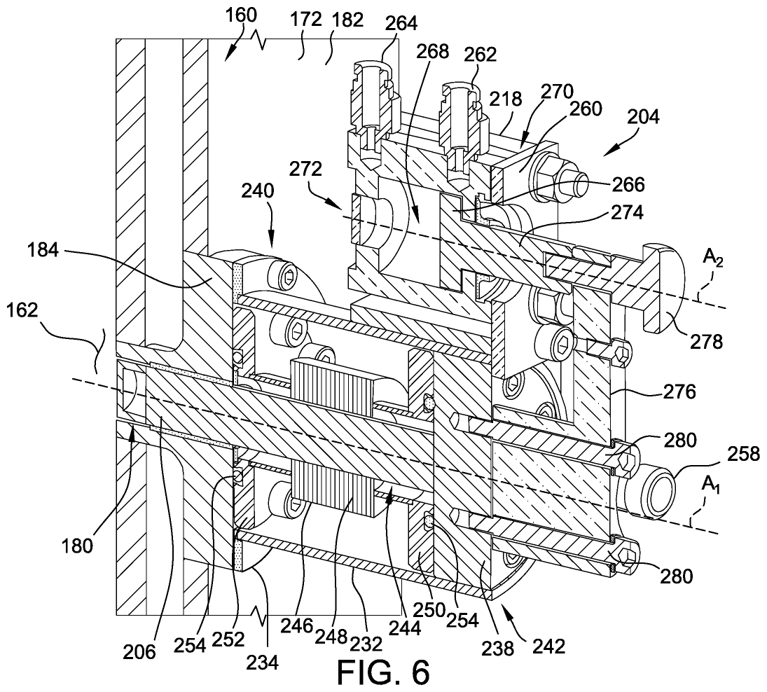

FIGS. 3-6 are views illustrating the feed assembly 200 in greater detail. FIG. 3 is a partial cross section of the ingot puller 100 showing the feed assembly 200 when the dumper 202 is opened. FIG. 4 is an isolated bottom section of the ingot receiving vessel 160 with the dumper 202 positioned therein, taken along a line extending through each of the opening pin assemblies 204 perpendicular to the longitudinal axis X. FIG. 5 is an enlarged perspective of one of the opening pin assemblies 204. FIG. 6 is a cross section of the opening pin assembly shown in FIG. 5.

FIG. 3 depicts the dumper 202 lowered in the ingot receiving chamber 162 and the annular stop 216 engaging the opening pins 206 that extend into the ingot receiving chamber 162 to open the dumper 202. A first end 220 of the sidewall 210 is released from the bottom 212 to define the charge chute 214 therebetween. The sidewall 210 includes a second end 222 opposite the first end 220. The second end 222 is open to receive polycrystalline semiconductor material into the interior volume 230 of the dumper 202. The sidewall 210 extends between the first end 220 and the second end 222 a height H₁, measured in a direction of the longitudinal axis X. The annular stop 216 is located on the sidewall 210 proximate the first end 220 and at a height H2 above the second end 222, measured in the direction of the axis X. The opening pin assemblies 204 are each located a height H₃ above the first vessel end 166. Suitably, the height H₃ is approximately the same for each opening pin assembly 204 such that the opening pins 206 engage the annular stop 216 at the same longitudinal location (i.e., along a common plane perpendicular to the axis X) within the ingot receiving chamber 162, to maintain axial alignment of the dumper 202 with the axis X when the dumper 202 is opened. The valve body 152 extends a height H₄ between the first valve end 154 and the second valve end 156.

The height H2 of the annular stop 216 is suitably approximately equal to or greater than the sum total of the height H₃ at which the opening pin assemblies 204 are located above the first vessel end 166 and the height H₄ of the valve body 152. As such, when the opening pins 206 engage the annular stop 216 to release the sidewall 210 from the bottom 212 and open the dumper 202, the first end 220 of the sidewall 210 and the bottom 212 extend through the receiving chamber inlet 164 and the valve passageway 158 and the charge chute 214 is positioned adjacent to the growth chamber outlet 110 and/or extends at least partially through the growth chamber outlet 110 and into the growth chamber 108. The charge chute 214 is suitably positioned adjacent to the growth chamber outlet 110 and/or partially within the growth chamber 108 when the dumper 202 is opened to provide a relatively short vertical distance for the polycrystalline silicon material 208 exiting the dumper 202 to flow into the crucible 104. In other examples, the height H2 of the annular stop 216 may be smaller than the sum total of the height H₃ and the height H₄, such that the charge chute 214 is positioned within the valve passageway 158 and/or the ingot receiving chamber 162 when the dumper 202 is opened.

Still referring to FIG. 3, the dumper bottom 212 is conically shaped and tapers inward from a base 224 towards an apex portion 226. The bottom 212 has an outer diameter D₁ at the base 224 that is approximately equal to or slightly greater than an inner diameter D₂ of the cylindrical sidewall 210. The outer diameter D₁ at the base 224 enables the bottom 212 to seal the dumper 202 and prevent the polycrystalline semiconductor material 208 from exiting therefrom when the first end 220 of the sidewall 210 is seated on the bottom 212.

The apex portion 226 of the bottom is attached to an opener plate 228 (e.g., using a fastener that extends through the apex portion 226). The opener plate 228 extends through the interior volume 230 of the dumper 202 along the longitudinal axis X and is connectable with the pull wire 124 shown in FIG. 2 (e.g., via the pulling assembly 126 shown in FIG. 1). The opener plate 228 is moveable relative to the sidewall 210 along the longitudinal axis X such that, when the annular stop 216 engages the opening pins 206 causing the sidewall 210 to release from the bottom 212, the bottom 212 continues to be lowered below the sidewall 210 thereby opening the charge chute 214 for the polycrystalline semiconductor material 208 to exit therethrough. The conical shape of the bottom 212 provides a sloped surface between the apex portion 226 and the base 224 of the bottom 212 to further facilitate flow of the polycrystalline semiconductor material 208 exiting through the charge chute 214.

The cylindrical sidewall 210 of the bottom 212 also defines the outer diameter D₃. The outer diameter D₁ of the base 224 of the bottom 212 is suitably approximately equal to or slightly smaller than the outer diameter D₃ of the sidewall 210. For example, the outer diameter D₁ of the base 224 may be greater than the inner diameter D₂ of the sidewall 210 to seal the interior volume 230 when the sidewall 210 is seated on the bottom 212 and approximately equal to or smaller than the outer diameter D₃ of the sidewall 210 such that the base 224 does not extend outward beyond the sidewall 210. The outer diameters D₁ and D₃ of the base 224 of the bottom 212 and the sidewall 210, respectively, are each smaller than each of the inner diameter D₄ of the ingot receiving vessel 160 and an inner diameter D₅ of the isolation valve 150. As such, the dumper 202 is able to be raised and lowered in the ingot receiving chamber 162 and the valve passageway 158 without contacting the ingot receiving vessel 160 or the isolation valve 150. The outer diameters D₁ and D₃ of the base 224 of the bottom 212 and the sidewall 210, respectively, may also each be smaller than an inner diameter (not labeled) of the growth chamber outlet 110 to enable the dumper 202 to be lowered into and raised from the growth chamber 108 without contacting the housing 106.

The annular stop 216 extends outward beyond the outer diameter D₃ of the dumper sidewall 210 to define a stop diameter D₆. The stop diameter D₆ is smaller than the inner diameter D₄ of the ingot receiving vessel 160. As such, the annular stop 216 is able to engage the opening pins 206 that clear the outer diameter D₃ of the sidewall 210 as the dumper 202 is being lowered, without the annular stop 216 contacting the ingot receiving vessel 160.

As shown in FIG. 4, three opening pin assemblies 204 are included in the example feed assembly 200. As described above, more or fewer opening pin assemblies 204 may be included in the example feed assembly 200. The opening pin assemblies 204 are located at approximately the same height H₃ (shown in FIG. 3) such that the opening pins 206 extend into the ingot receiving chamber 162 substantially along a common plane that intersects the longitudinal axis X. The opening pin assemblies 204 are connected to the sidewall 172 of the ingot receiving vessel 160 at suitable angular positions to balance the engagement of the opening pins 206 with the annular stop 216 and cause the dumper 202 to open while maintaining axial alignment of the dumper 202 with the longitudinal axis X. In the example feed assembly 200, adjacent opening pin assemblies 204 are located at equally spaced angular positions. That is, each opening pin assembly 204 is spaced an arc measure θ from each adjacent opening pin assembly 204, and the arc measures θ between adjacent opening pin assemblies 204 are approximately equal. For example, where three opening pin assemblies 204 are included in the feed assembly, each opening pin assembly 204 is spaced an arc measure of approximately 120° from each adjacent opening pin assembly 204. In other examples, where two opening pin assemblies 204 are included, the opening pin assemblies 204 may be spaced an arc measure of approximately 180° from each other, where four opening pin assemblies 204 are included, the opening pin assemblies 204 may be spaced an arc measure of approximately 90° from each adjacent opening pin assembly 204, and so on.

Referring to FIGS. 5 and 6, the opening pin assemblies 204 are similar in configuration and will be described with reference to the single opening pin assembly 204 shown in FIGS. 5 and 6. The opening pin assembly 204 includes the opening pin 206 and the actuator 218 that is operably connected to the opening pin 206 and controllable to cause the opening pin 206 to extend into and retract from the ingot receiving chamber 162. The opening pin assembly 204 includes a guide barrel 232 that is connected to the sidewall 172 of the ingot receiving vessel 160 at the height H₃ (FIG. 3) above the first vessel end 166. The guide barrel 232 includes an end flange 234 at a first end 240. The end flange 234 is attached to a corresponding vessel flange 184 formed on an outer surface 182 of the sidewall 172 of the ingot receiving vessel 160. The vessel flange 184 surrounds the corresponding opening 180 in the sidewall 172 through which the opening pin 206 extends into and retracts from the ingot receiving chamber 162. The guide barrel 232 is axially aligned with the corresponding opening 180 when attached to the vessel flange 184. The end flange 234 of the guide barrel 232 is attached to the vessel flange 184 by fasteners 186 (e.g., screws) that extend through the flanges 184, 234.

The opening pin assembly 204 includes a piston head 238 moveable within the guide barrel 232 along a lateral axis A₁. The axis A₁ extends substantially perpendicular to the longitudinal axis X (shown in FIGS. 1-3). The opening pin 206 extends outward from the piston head 238 and into the opening 180. The opening pin 206 may be described herein as including the piston head 238, which encompasses configurations in which the opening pin 206 is integral with the piston head 238 and configurations in which the opening pin 206 is connected with the piston head 238. Movement of the piston head 238 within the guide barrel 232 along the axis A₁ causes the opening pin 206 to extend into and retract from the ingot receiving chamber 162 through the opening 180. In particular, the piston head 238 reciprocates between a first position (shown in FIGS. 3 and 4), also referred to as an extended position, in which the opening pin 206 extends into the ingot receiving chamber 162, and a second position (shown in FIGS. 5 and 6), also referred to as a retracted position, in which the opening pin 206 is retracted from the ingot receiving chamber 162.

When the piston head 238 is in the retracted position, as shown in FIGS. 5 and 6, the piston head 238 is positioned adjacent to a second end 242 of the guide barrel 232 opposite the end flange 234 and the opening pin 206 is retracted from the ingot receiving chamber 162. A portion of the opening pin 206 remains in the opening 180 when the pin 206 is retracted, as shown in FIG. 6, to maintain alignment between the opening pin 206 and the opening 180 along the axis A₁ when the piston head 238 is moved towards an extended position (shown in FIGS. 3 and 4). The piston head 238 moves towards the first end 240 of the guide barrel 232 along the axis A₁ when moving towards the extended position. When the piston head 238 is in the extended position, the piston head 238 is positioned between the first end 240 and the second end 242 of the guide barrel 232 and the opening pin 206 extends into the ingot receiving chamber 162. The piston head 238 may alternatively be positioned adjacent to the first end 240 of the guide barrel when in the extended position.

The term “retract” and its derivatives used to describe the positioning of the opening pin 206 within the ingot receiving chamber 162 refer to the pin 206 extending a smaller distance into the ingot receiving chamber 162 than when extended therein. In some examples, a portion of the opening pin 206 may remain within the ingot receiving chamber 162 when the piston head 238 is in the retracted position and the pin 206 is retracted from the ingot receiving chamber 162. The term “extend” and its derivatives used to describe the positioning of the opening pin 206 within the ingot receiving chamber 162 refer to the pin 206 extending a greater distance into the ingot receiving chamber 162 than when retracted therefrom. In some examples, a portion of the opening pin 206 may remain outside the ingot receiving chamber 162 (e.g., within the opening 180 or within the guide barrel 232) when the piston head 238 is in the extended position and the pin 206 extends into the ingot receiving chamber 162.

As shown in FIG. 6, the opening pin assembly 204 also includes a metal bellows 246 positioned in the guide barrel 232 between the first end 240 and the piston head 238. The metal bellows 246 surrounds the opening pin 206 and defines an interior volume 244 therebetween. The metal bellows 246 is operatively connected to the piston head 238 by a first support flange 250 (e.g., using fasteners). The metal bellows 246 also includes a second support flange 252 opposite the first support flange 250, and the second support flange 252 is connected to the vessel flange 184 (e.g., using fasteners). The metal bellows 246 may be made of any suitable flexible metal material (e.g., stainless steel).

The metal bellows 246 includes a diaphragm 248 between the first and second support flanges 250, 252. The diaphragm 248 surrounds the opening pin 206 within the guide barrel 232. The diaphragm 248 selectively expands and compresses as the piston head 238 reciprocates between the retracted position and the extended position, respectively. FIG. 6 shows the diaphragm 248 in an expanded state when the piston head 238 is in the retracted position adjacent the second end 242 of the guide barrel 232. As the piston head 238 moves towards the extended position, the diaphragm 248 compresses within the guide barrel 232. A pressure that exists in the volume 244 between the diaphragm 248 and the opening pin 206 is substantially the same as a pressure within the ingot receiving chamber 162. O-rings 254 are seated between the first support flange 250 and the piston head 238 and between the second support flange 252 and the vessel flange 184 to create a seal therebetween and maintain the pressure between the diaphragm 248 and the opening pin 206. The diaphragm 248 enables movement of the piston head 238, and thereby movement of the opening pin 206, within the guide barrel 232 under vacuum in the volume 244.

The opening pin 206 may be exposed to relatively high temperatures due to its proximity to the ingot receiving chamber 162 and/or growing ingot during an ingot growth process. Cooling fluid (e.g., cooling water) may be supplied to the opening pin 206 to provide cooling to the opening pin 206. Fluid inlet and outlet ports 256 and 258 extend through and outward from the piston head 238 for connecting a cooling fluid supply (not shown), such as a cooling water supply, with the opening pin 206. The fluid inlet port 256 enables cooling fluid to be supplied to the opening pin 206 and the fluid outlet port 258 enables the cooling fluid to exit the opening pin 206. Cooling fluid supplied to the opening pin 206 may circulate around and/or through the opening pin 206 to provide cooling. For example, cooling channels (not shown) may be formed in the opening pin 206 to enable cooling fluid supplied via the inlet port 256 to circulate through the opening pin 206 and exit via the outlet port 258. Additionally and/or alternatively, the opening pin 206 may include a cooling jacket for receiving the cooling fluid and circulating the cooling fluid around the pin 206. A controller (e.g., the controller 140 shown in FIGS. 1-3) may selectively control supply of the cooling fluid to the opening pin 206.

The piston head 238 is moveable between the extended position and the retracted position by operation of the actuator 218. In the example feed assembly 200, the actuator 218 is a pneumatic cylinder. In other examples, any suitable actuator may be used as the actuator 218 in one or more of the opening pin assemblies 204 to enable the feed assembly 200 to function as described. For example, the actuator 218 may include a linear actuator, a rotary actuator, a hydraulic cylinder, an electric actuator, and the like. The actuator 218 of each opening assembly 204 is connected to a controller (e.g., the controller 140 shown in FIGS. 1-3). The controller 140 controls the actuators 218 to cause the respective opening pin 206 to extend into and retract from the ingot receiving chamber 162. The actuators 218 may be referred to as pneumatic cylinders 218, but this description does not limit the actuators 218 to any type of actuator.

The pneumatic cylinder 218 is mounted on the guide barrel 232 using a mounting plate 260. The mounting plate 260 is connected to a first cylinder end 270 of the pneumatic cylinder 218 and the second end 242 of the guide barrel 232 (e.g., using fasteners). The pneumatic cylinder 218 includes a gas inlet port 262 and a gas outlet port 264 for connecting the pneumatic cylinder 218 with a pressurized gas supply (not shown), such as a pressurized air supply. The pneumatic cylinder 218 also includes a piston 266 that reciprocates in a cylinder channel 268 in response to pressurized gas (e.g., pressurized air) supplied to or removed from the pneumatic cylinder 218. A controller (e.g., the controller 140 shown in FIGS. 1-3) may selectively control supply and removal of the pressurized gas to and from the pneumatic cylinder 218 to thereby selectively control movement of the piston 266 in the cylinder channel 268. The piston 266 reciprocates in the cylinder channel 268 along a lateral axis A₂ between the first cylinder end 270 and a second cylinder end 272. The lateral axis A₂ extends substantially parallel to the lateral axis A₁ along which the piston head 238 reciprocates in the guide barrel 232.

The piston 266 includes a piston rod 274 extending from the piston 266 along the lateral axis A₂. When the piston 266 is positioned adjacent the first cylinder end 270 (as shown in FIG. 6), the piston rod 274 extends outward from the pneumatic cylinder 218. When the piston 266 moves toward the second cylinder end 272, the piston rod 274 retracts into the cylinder channel 268.

The piston rod 274 is connected to the piston head 238 of the opening pin assembly 204 by a connector arm 276. The connector arm 276 is connected to the piston rod 274 by a manual knob 278 and to the piston head 238 using fasteners 280. The connector arm 276 translates movement of the piston 266 along the axis A₂ to movement of the piston head 238 along the axis A₁. For example, the connector arm 276 translates movement of the piston 266 towards the second cylinder end 272, which may be caused by pressurized gas supplied to the cylinder channel 268, to movement of the piston head 238 towards the extended position. The connector arm 276 also translates movement of the piston 266 towards the first cylinder end 270, which may be caused by pressurized gas exiting the cylinder channel 268, to movement of the piston head 238 towards the retracted position. The manual knob 278 may be used by an operator, in addition to or in the alternative to a controller, to manually reciprocate the piston 266 in the cylinder channel 268 and, thereby, to reciprocate the piston head 238 in the guide barrel 232.

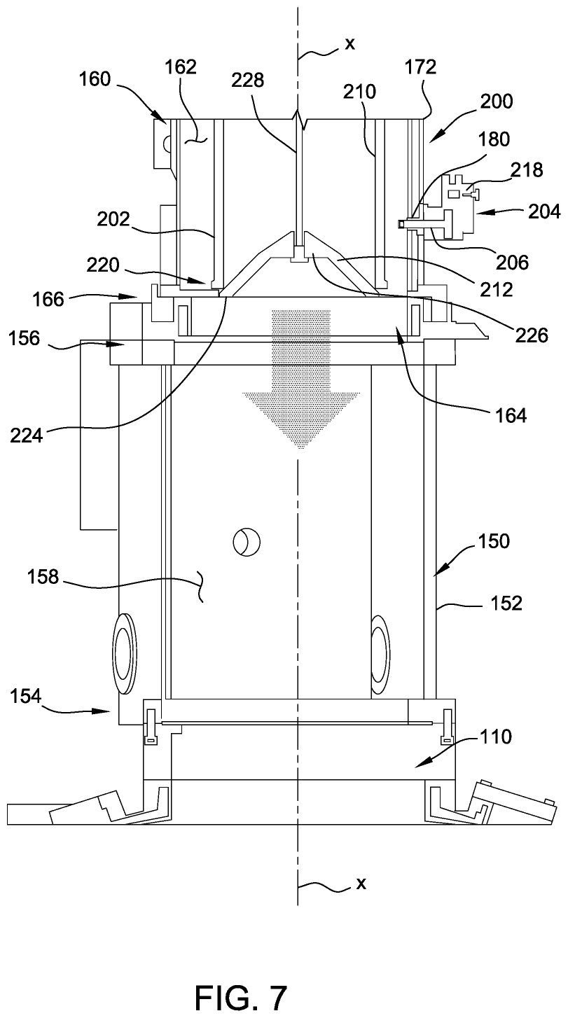

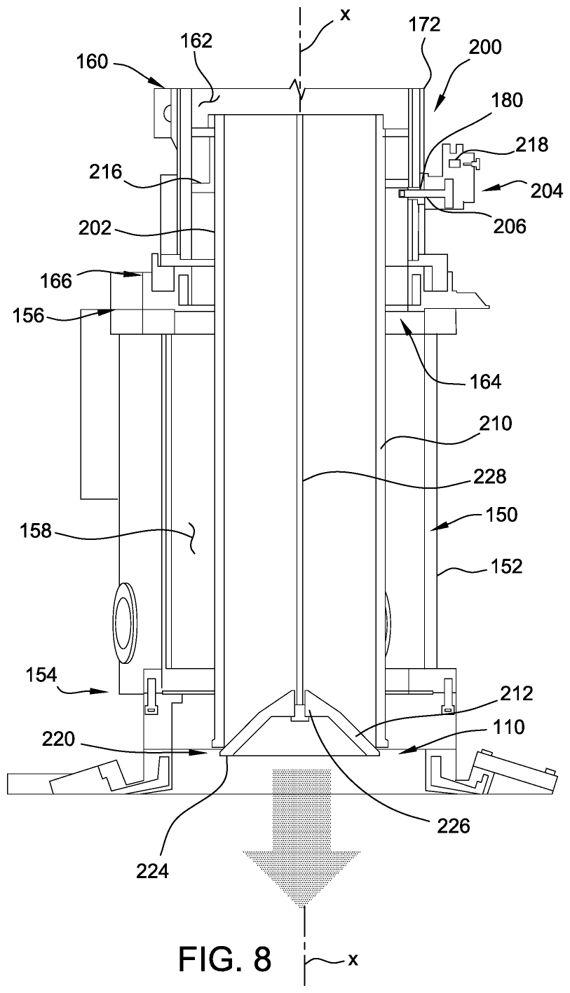

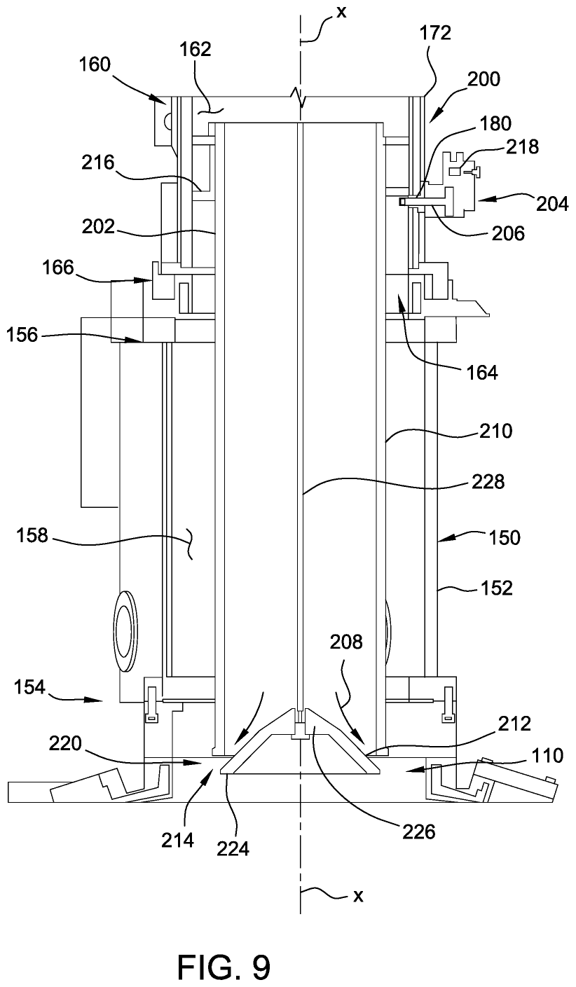

Referring to FIGS. 1-6 and with additional reference to FIGS. 7-9, operation of the feed assembly 200 for charging polycrystalline semiconductor material (e.g., polycrystalline silicon) to the crucible 104 of the ingot puller 100 will now be described. FIGS. 7-9 are partial cross sections of the ingot puller 100 and respectively illustrate steps in a sequence of moving the dumper 202 of the feed assembly 200 from a raised position (FIG. 7) in the ingot receiving chamber 162 to a lowered position (FIGS. 8 and 9).

In operation, the dumper 202 is initially moved to the raised position within the ingot receiving chamber 162. This may be performed before the ingot receiving vessel 160 is seated on the isolation valve 150. The opener plate 228 is connected with the pull wire 124 (e.g., via the pulling assembly 126) or another suitable pulling means for raising and lowering the dumper 202 in the ingot receiving chamber 162. The winch 132 or other suitable pulling means may then raise the dumper 202 through the receiving chamber inlet 164 and to the raised position in the ingot receiving chamber 162. At this stage, the dumper 202 contains a suitable amount of polycrystalline semiconductor material for charging to the crucible. The dumper sidewall 210 is seated on the dumper bottom 212 to seal the polycrystalline semiconductor material in the dumper 202.

The opening pin 206 of each opening pin assembly 204 is retracted from the ingot receiving chamber 162 (shown in FIG. 5) to enable the dumper 202 to be raised to the raised position shown in FIG. 7. That is, the opening pins 206 are retracted such that the opening pins 206 do not engage the annular stop 216 of the dumper sidewall 210 during upward movement of the dumper 202 to the raised position. Retraction of the opening pin 206 is caused by the piston head 238 moving to the retracted position. The pneumatic cylinder 218 of the opening pin assembly 204 may cause the piston head 238 to move towards the retracted position. For example, the controller 140 may control supply of pressurized gas to the pneumatic cylinder 218, causing the piston 266 to move towards the first cylinder end 270, which is translated to movement of the piston head 238 to the retracted position by the connector arm 276. Additionally and/or alternatively, an operator may manually retract the opening pin 206 by applying a pulling force to the manual knob 278, causing the piston 266 to move towards the first cylinder end 270, which is translated to movement of the piston head 238 to the retracted position by the connector arm 276. The diaphragm 248 of the metal bellows 246 expands to enable the piston head 238 to move to the retracted position.

When the dumper 202 is moved to the raised position shown in FIG. 7, the dumper 202 is accommodated within the ingot receiving chamber 162 such that the bottom 212 does not extend downward beyond the first vessel end 166. The first vessel end 166 of the ingot receiving vessel 160 is connected to the second valve end 156 of the isolation valve 150 and secured thereto using the clamp 176. The isolation valve 150 is opened at this stage to provide communication between the growth chamber 108, the valve passageway 158, and the ingot receiving chamber 162. The dumper 202 is axially aligned with the growth chamber 108, the valve passageway 158, and the ingot receiving chamber 162 along the axis X. With the dumper 202 in the raised position in the ingot receiving chamber 162, the ingot receiving vessel 160 connected to the isolation valve 150, and the isolation valve 150 opened, the polycrystalline silicon material is charged to the crucible 104 using the feed assembly 200.

The sequence between FIGS. 7 and 8 depicts the dumper 202 being lowered in the ingot receiving chamber 162 towards the lowered position (shown in FIGS. 8 and 9) along the axis X during the charging operation. As the dumper 202 is being lowered, the opening pins 206 extend into the ingot receiving chamber 162. Extension of the opening pin 206 is caused by the piston head 238 moving to the extended position. This may be controlled by the controller 140, which controls supply of pressurized gas to the pneumatic cylinder 218, causing the piston 266 to move towards the second cylinder end 272. The connector arm 276 translates movement of the piston 266 to the second cylinder end 272 to movement of the piston head 238 to the extended position. Additionally and/or alternatively, an operator may manually extend the opening pin 206 into the ingot receiving chamber 162 by applying a pushing force to the manual knob 278, causing the piston 266 to move towards the second cylinder end 272, which is translated to movement of the piston head 238 to the extended position by the connector arm 276. The diaphragm 248 of the metal bellows 246 compresses to enable the piston head 238 to move to the extended position.

The sequence between FIGS. 8 and 9 depicts the dumper 202 being opened by engagement between the opening pins 206 that extend into the ingot receiving chamber 162 and the annular stop 216 of the dumper sidewall 210 when the dumper 202 is moved to the lowered position. The first end 220 of the dumper sidewall 210 remains seated on the dumper bottom 212 as the dumper 202 is lowered in the ingot receiving chamber 162 towards the lowered position, to prevent the polycrystalline semiconductor material from prematurely exiting the dumper 202. In the lowered position of the dumper 202, the dumper 202 extends through the valve passageway 158 and the first end 220 of the dumper sidewall 210 and the dumper bottom 212 are adjacent to the growth chamber outlet 110. The dumper sidewall 210 and the dumper bottom 212 may, in some examples, extend into the growth chamber 108 when the dumper 202 is in the lowered position. The opening pins 206 engage the annular stop to release the dumper sidewall 210 from the dumper bottom 212 as shown in FIG. 9. The charge chute 214 is thereby defined between the first end 220 of the dumper sidewall 210 and the dumper bottom 212. The polycrystalline semiconductor material 208 exits the dumper 202 via the charge chute 214 and is charged into the crucible 104.

After the polycrystalline semiconductor material 208 is charged into the crucible 104, the opening pins 206 may retract from the ingot receiving chamber 162 as described above and the dumper 202 is again raised to the raised position shown in FIG. 7. The ingot receiving vessel 160 is then removed from the isolation valve 150 to enable removal of the dumper 202 from the ingot receiving chamber 162. With the ingot receiving vessel 160 removed from the isolation valve 150, the dumper 202 is lowered from the ingot receiving chamber 162. The opening pins 206 remain retracted to not interfere with the annular stop 216 and enable to dumper 202 to be lowered out of the ingot receiving chamber 162. The opener plate 228 is removed from the pull wire 124 and the dumper 202 is removed from the ingot receiving vessel 160.

The pulling assembly 126 may then be configured with a seed crystal 130 for an ingot growth process and the ingot receiving vessel 160 is again connected to the isolation valve 150. An ingot growth process may then proceed as described above with heating the charge of polycrystalline silicon material in the crucible 104 by the heating system 122 to produce the silicon melt 102. Process gas is introduced into the growth chamber 108 through the inlet port 114, the ingot receiving chamber 162, and the valve passageway 158. The winch 132 lowers the seed crystal 130 through the ingot receiving chamber 162 and the valve passageway 158 and into the growth chamber 108 until the seed crystal 130 contacts the surface of the silicon melt 102. A growing ingot may be pulled in the direction of the longitudinal axis X through the growth chamber 108, the valve passageway 158, and finally into the ingot receiving chamber 162. The opening pins 206 remain retracted from the ingot receiving chamber 162 as the ingot is pulled therein to not interfere with the growing ingot.

Advantageously, examples described in this disclosure include an automated feed assembly for charging semiconductor material into a crucible of an apparatus used to produce a single crystal semiconductor ingot. An example feed assembly is equipped with a dumper containing semiconductor material for charging into the crucible and automated opening pin assemblies for causing the dumper to open, allowing the semiconductor material to exit the dumper. The automated control of the feed assembly facilitates reducing or eliminating operator error in installing manual feed assemblies and/or creates the opportunity for a fully automated ingot growth process using the apparatus. The opening pin assemblies also include components that enable manual operation thereof in the event of controller error or outage.

The terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a”, “an”, “the” and “said” are intended to mean that there are one or more of the elements. The terms “comprising,” “including,” “containing” and “having” are intended to be inclusive and mean that there may be additional elements other than the listed elements. The use of terms indicating a particular orientation (e.g., “top”, “bottom”, “side”, “horizontal”, “vertical”, “lateral”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. An ingot puller for producing a single crystal semiconductor ingot, the ingot puller comprising:
a housing defining a growth chamber;
a crucible positioned within the growth chamber;
an ingot receiving vessel defining an ingot receiving chamber connected with the growth chamber; and
a feed assembly for charging semiconductor material to the crucible, the feed assembly comprising:
a dumper for containing the semiconductor material, the dumper being moveable in the ingot receiving chamber between a raised position and a lowered position, the dumper comprising a dumper bottom and a dumper sidewall extending from the dumper bottom, the dumper sidewall being releasable from the dumper bottom to allow the semiconductor material to exit the dumper; and
opening pins selectively extendable into the ingot receiving chamber and retractable from the ingot receiving chamber, wherein the opening pins engage the dumper when extended into the ingot receiving chamber to release the dumper sidewall from the dumper bottom as the dumper is moved towards the lowered position.

2. The ingot puller of claim 1, wherein each opening pin is operably connected to a respective actuator that selectively causes the opening pin to extend into and retract from the ingot receiving chamber.

3. The ingot puller of claim 2, further comprising a controller for controlling each actuator to cause the respective opening pin to selectively extend into and retract from the ingot receiving chamber.

4. The ingot puller of claim 2, wherein each actuator comprises a pneumatic cylinder.

5. The ingot puller of claim 4, wherein each opening pin includes a piston head connected to a piston rod of the pneumatic cylinder by a connector arm, each piston head being reciprocable within a respective guide barrel attached to the ingot receiving vessel between a first position in which the opening pin extends into the ingot receiving chamber, and a second position in which the opening pin is retracted from the ingot receiving chamber.

6. The ingot puller of claim 5, wherein a metal bellows is positioned in each guide barrel, the metal bellows operably connected to the respective piston head to enable the piston head to reciprocate between the first position and the second position.

7. The ingot puller of claim 5, wherein each piston head includes cooling fluid inlet and outlet ports for connecting the respective opening pin with a cooling fluid supply.

8. The ingot puller of claim 1, wherein each opening pin is manually operable to selectively extend into and retract from the ingot receiving chamber.

9. The ingot puller of claim 1, wherein the dumper includes an annular stop that extends outward from the dumper sidewall, wherein the opening pins engage the annular stop when extended into the ingot receiving chamber to release the dumper sidewall from the dumper bottom as the dumper is moved towards the lowered position.

10. An ingot puller for producing a single crystal semiconductor ingot, the ingot puller comprising:
a housing defining a growth chamber and a growth chamber outlet;
a crucible positioned within the growth chamber;
a feed assembly for charging semiconductor material to the crucible, the feed assembly comprising:
a dumper for containing semiconductor material and comprising a dumper bottom and a dumper sidewall releasable from the dumper bottom to define a charge chute for the semiconductor material to exit the dumper, the dumper being moveable between a raised position and a lowered position; and
opening pin assemblies each comprising an opening pin selectively extendable into engagement with the dumper to release the dumper sidewall from the dumper bottom as the dumper is moved towards the lowered position, the charge chute being defined and located adjacent to the growth chamber outlet or within the growth chamber when the dumper is in the lowered position, and an actuator that causes the opening pin to extend into engagement with the dumper; and
a controller for controlling each actuator to cause the respective opening pin to extend into engagement with the dumper.

11. The ingot puller of claim 10, further comprising an ingot receiving vessel defining an ingot receiving chamber connected with the growth chamber outlet, the dumper being moveable in the ingot receiving chamber, the opening pin assemblies being connected to the ingot receiving vessel, and the opening pins being selectively extendable into the ingot receiving chamber.

12. The ingot puller of claim 11, wherein the feed assembly comprises three opening pin assemblies connected to the ingot receiving vessel.

13. The ingot puller of claim 10, wherein each opening pin assembly is manually operable to selectively cause the opening pin to extend into engagement with the dumper.

14. The ingot puller of claim 10, wherein each opening pin includes a piston head connected to the respective actuator that causes the piston head to reciprocate within a guide barrel of the respective opening pin assembly between a first position in which the opening pin extends into engagement with the dumper, and a second position in which the opening pin is retracted out of engagement with the dumper.

15. The ingot puller of claim 14, wherein each actuator is a pneumatic cylinder that includes a piston rod connected to the piston head of the respective opening pin by a connector arm that translates movement of the piston rod to movement of the piston head within the guide barrel.

16. The ingot puller of claim 14, wherein a metal bellows is positioned in each guide barrel, the metal bellows operably connected to the respective piston head to enable the piston head to reciprocate between the first position and the second position.

17. The ingot puller of claim 10, wherein each opening pin assembly includes fluid inlet and outlet ports for connecting the opening pin with a cooling fluid supply.

18. A method of producing a single crystal semiconductor ingot from a semiconductor melt using an ingot puller, the method comprising:
positioning a crucible within a growth chamber defined by a housing of the ingot puller;
connecting an ingot receiving vessel defining an ingot receiving chamber to the housing;
lowering a dumper in the ingot receiving chamber, the dumper containing semiconductor material;
controlling, using a controller, opening pins to extend into the ingot receiving chamber to cause the dumper to open and allow the semiconductor material to exit the dumper and flow into the crucible;
heating the semiconductor material to cause a semiconductor melt to form in the crucible; and
pulling a single crystal semiconductor ingot from the semiconductor melt.

19. The method of claim 18, further comprising:
controlling, using the controller, the opening pins to retract from the ingot receiving chamber; and
removing the dumper from the ingot receiving chamber when the opening pins are retracted.

20. The method of claim 19, further comprising pulling the single crystal semiconductor ingot into the ingot receiving chamber after the dumper is removed.
